(19) United States
(12) Patent Application Publication
(10) Pub. No.: US 2012/0262195 A1
(43) Pub. Date: Oct. 18, 2012

(54) RESISTANCE DETERMINING SYSTEM AND METHOD

(75) Inventors: PENG CHEN, Shenzhen City (CN); QI-YAN LUO, Shenzhen City (CN); YUN BAI, Shenzhen City (CN); FU-SEN YANG, Shenzhen City (CN); SONG-LIN TONG, Shenzhen City (CN)

(73) Assignees: HON HAI PRECISION INDUSTRY CO., LTD., Tu-Cheng (TW); HON FU JIN PRECISION INDUSTRY(ShenZhen) CO., LTD., Shenzhen City (CN)

(21) Appl. No.: 13/283,604

(22) Filed: Oct. 28, 2011

(30) Foreign Application Priority Data
Apr. 13, 2011 (CN) 201110091440.9

(51) Int. Cl. G01R 27/08

(52) U.S. Cl. 324/705

(57) ABSTRACT

A resistance determining system is used to determine an offsetting resistance of a mainboard to establish a predetermined offset voltage. The system includes an input equipment, a single-chip, and a resistor. The input equipment sets a predetermined standard voltage of the mainboard. The resistor supplies the mainboard with various resistances, to adjust real output voltage of the mainboard. The single-chip monitors the real output voltage of the mainboard, and adjusts the resistance of the resistor until the difference between the real output voltage and the predetermined standard voltage is equal to a predetermined offset voltage.

### BACKGROUND

1. Technical Field

The present disclosure relates to resistance determining systems and methods, and particularly to an offsetting resistance determining system and a method for determining an offsetting resistance using the same.

2. Description of Related Art

Voltage variations in a standard supply voltage may be needed in relation to a mainboard, to make the mainboard operate correctly and reliably using a specified range of the standard supply voltage. The standard voltage supply is determined by Voltage Identification (VID) signals from a CPU. The variation(s) from a standard voltage level (offset voltage) is determined by an offsetting resistance which is connected to a pulse width modulation (PWM) chip of the mainboard, for controlling the PWM chip to adjust the voltage of the mainboard. A method for determining the offsetting resistance usually includes manually changing out different resistors on a trial-and-error basis, until the difference between the real output voltage value and the standard voltage value is equal to the predetermined offset voltage value, which is an inconvenient and inefficient method. What is needed, therefore, is a resistance determining system and method, which can overcome the above shortcomings.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a block diagram of an exemplary embodiment of a resistance determining system.

FIG. 2 shows a flowchart illustrating an exemplary embodiment of a method of using the resistance determining system of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

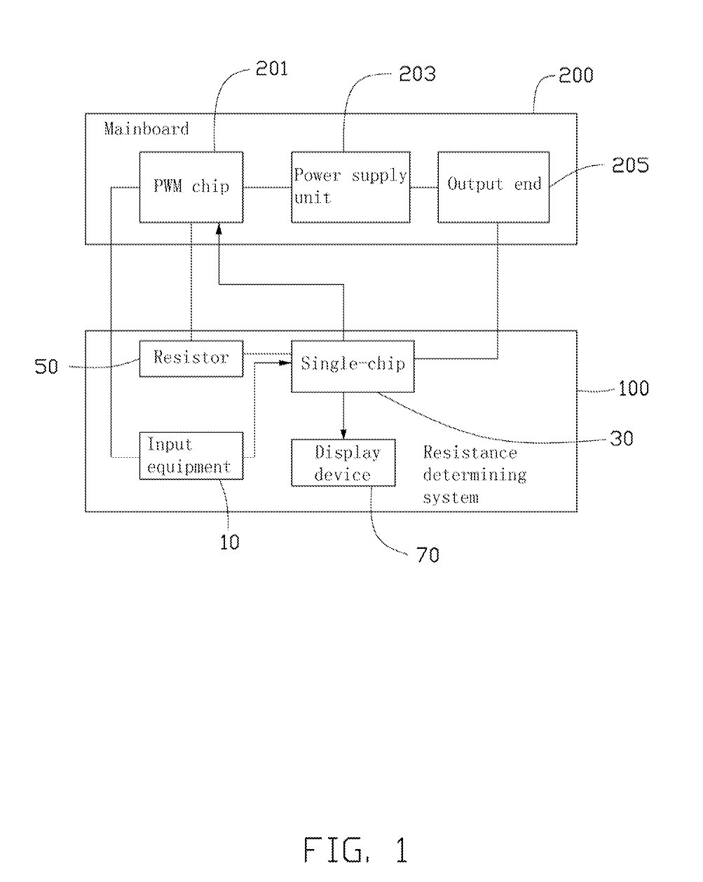

FIG. 1 is a block diagram of an exemplary embodiment of a resistance determining system 100. The system 100 can be used to determine an offsetting resistance of a mainboard 200. The offsetting resistance is a resistance that is used to establish a predetermined offset voltage, to combine a predetermined standard voltage with the offset voltage, to reach a predetermined voltage range. In this exemplary embodiment, the resistance determining system 100 determines the offsetting resistance, which provides the predetermined offset voltage for the mainboard 200, when the mainboard 200 is off-load (the mainboard 200 is not connected to a CPU, or the CPU is not working).

The system 100 includes an input equipment 10, a single-chip 30, a resistor 50, and a display device 70. The input equipment 10 sets the predetermined standard voltage of the mainboard 200. The resistor 50 is a digital resistor whose resistance is variable and readable by the single-chip 30. The resistor 50 supplies the mainboard 200 with various resistances, to adjust the real output voltage of the mainboard 200. In one exemplary embodiment, the resistor 50 can be an X9241-type digital resistor. The single-chip 30 determines whether the difference between a real output voltage and the predetermined standard voltage of the mainboard 200 is equal to the predetermined offset voltage, and then adjusts the resistance of the resistor 30 accordingly. The display device 70 displays the real output voltage value of the mainboard 200, the offset voltage, and the resistance value of the resistor 50.

The mainboard 200 includes a pulse width modulation (PWM) chip 201, a voltage power supply unit 203 connected to the PWM chip 201, and an output end 205. The PWM chip 201 controls the power supply unit 203 to output the predetermined standard voltage via the output end 205. The PWM chip 201 is connected to both the resistor 50 and the single-chip 30. In this exemplary embodiment, the mainboard 200 is off-load, and in this condition, the input equipment 10 sends the voltage identification digital (VID) signals instead of the CPU sending VID signals, so that the PWM chip 201 can control the power supply unit 203 to output voltages according to the VID signals.

The input equipment 10 is electronically connected to the single-chip 30, and sends the predetermined standard voltage signal to the PWM chip 201 via the single-chip 30, to set the predetermined standard voltage. The predetermined standard voltage signal can be represented by a decimal or binary system. In one exemplary embodiment, the input equipment 10 can be a keyboard.

The single-chip 30 is connected to the output end 205, and monitors the real output voltage of the mainboard 200. The single-chip 30 further determines whether the difference between the real output voltage value and the predetermined standard voltage value is equal to the predetermined offset voltage value. When the input equipment 10 sends a decimal number to set the predetermined standard voltage, the single-chip 30 stores the decimal number in memory. The single-chip 30 is programmed to convert the decimal number into a VID signal in 8-bit binary, and sends the 8-bit VID signal to the PWM chip 201. When the input equipment 10 sends an 8-bit binary signal to set the standard voltage, the single-chip 30 receives the signal and then sends the binary code to the PWM chip 201. Meanwhile the single-chip 30 converts the binary code into a decimal number and stores the converted decimal number in memory. In this exemplary embodiment, the single-chip 30 adjusts the resistance of the resistor 50 according to the difference between the real output voltage value from the output end 205 and the predetermined standard voltage value set by the input equipment 10, until the difference is equal to the predetermined offset voltage. Then the single-chip 30 reads the resistance value of the resistor 50, the real output value from the output end 205, and the offset voltage value, and then displays them on the display device 70. In one exemplary embodiment, the single-chip 30 can be a PIC16F73-type single-chip.

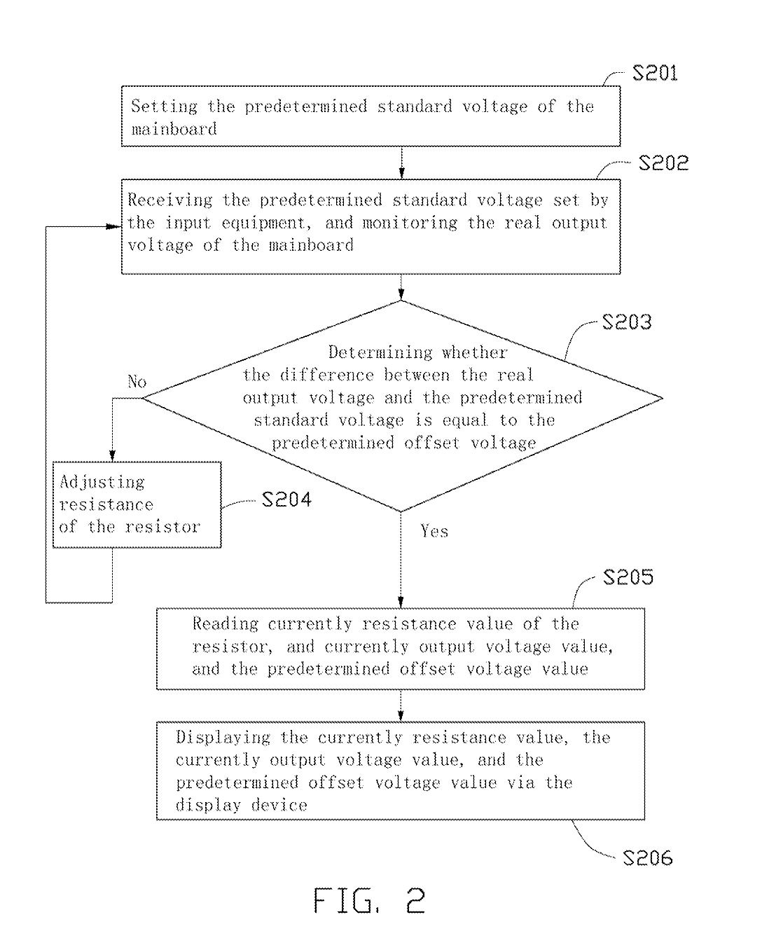

FIG. 2 is a flowchart illustrating an exemplary embodiment of a method of using the resistance determining system 100 to determining the offsetting resistance of the mainboard 200. In the flowchart, it is assumed that the mainboard 200 is off-load. Depending on the embodiment, certain of the blocks described may be removed, others may be added, and the sequence of the blocks may be altered. The description and the claims drawn for a method may include some indication in reference to certain steps, however, the indication used is only to be viewed for identification purposes and not as a suggestion as to an order for the blocks.

In block S201, the input equipment 10 sets the predetermined standard voltage of the mainboard 200.

In block S202, the single-chip 30 receives the standard voltage set by the input equipment 10, and monitors the real output voltage of the mainboard 200.

In block S203, the single-chip 30 determines whether the difference between the real output voltage value and the predetermined standard voltage value is equal to the predetermined offset voltage value. If any such event occurs, block 205 is implemented. If such events have not occurred, block 204 is implemented.

In block S204, in response to the difference not being equal to the predetermined offset voltage, the single-chip 30 adjusts the resistance of the resistor 50, and the process returns to block 203.

In block S205, where the difference is equal to the predetermined offset voltage, the single-chip 30 reads the current resistance of the resistor 50, the current output voltage, and the predetermined offset voltage.

In block S206, the single-chip 30 displays the current resistance of the resistor 50, the current output voltage, and the predetermined offset voltage via the display device 70.

What is claimed is:

1. A resistance determining system for determining an offsetting resistance of a mainboard to establish a predetermined offset voltage, the resistance determining system comprising:
an input equipment, for setting a predetermined standard voltage of the mainboard when the mainboard is off-load;
a resistor capable of providing different resistances to the mainboard, to adjust a real output voltage of the mainboard; and
a single-chip that adjusts resistance of the resistor according to the difference between a real output voltage value of the mainboard and the predetermined standard voltage value, until the difference is equal to the predetermined offset voltage value.

2. The system of claim 1, wherein the mainboard comprises a pulse width modulation (PWM) chip, a power supply unit, and an output end, the single-chip is connected to the PWM chip and the output end, the input equipment is connected to the single-chip, the single-chip receives the predetermined standard voltage signal set by the input equipment, and then sends the predetermined standard voltage signal to the PWM chip, the PWM chip controls the power supply unit to output the predetermined standard voltage via the output end according to the predetermined standard voltage signal.

3. The system of claim 1, wherein the predetermined standard voltage from the input equipment is a binary code, the single-chip sends the binary code to the PWM chip, and converts the binary code into a decimal number, to compare the predetermined standard voltage value and the real output voltage value.

4. The system of claim 1, wherein the predetermined standard voltage from the input equipment is a decimal number, the single-chip converts the decimal number into a binary code and sends the converted code to the PWM chip, and compares the predetermined standard voltage value and the real output voltage value.

5. The system of claim 1, further comprising a display unit that displays the offsetting resistance of the mainboard.

6. A method for determining an offsetting resistance of a mainboard to establish a predetermined offset voltage via a resistance determining system, wherein the mainboard is off-load, the resistance determining system comprises an input equipment, a single-chip, and a resistor, the method comprising:
setting a predetermined standard voltage of the mainboard;
monitoring difference between a real output voltage value and the predetermined standard voltage value of the mainboard, and determining whether the difference is equal to the predetermined offset voltage value;
in response to the difference being equal to the predetermined offset voltage value, adjusting the resistance of the resistor.

7. The method of claim 6, wherein the mainboard comprises a PWM chip and a power supply unit, the step setting a predetermined standard voltage of the mainboard comprises: the input equipment sends a predetermined voltage signal to the PWM chip via the single-chip, the PWM chip controls the power supply unit to output voltage according to the predetermined voltage signal.

8. The method of claim 6, further comprising displaying the real output voltage and the offsetting resistance determined by the system.
